(19) United States
(12) Patent Application Publication
(10) Pub. No.: US 2015/0313041 A1
(43) Pub. Date: Oct. 29, 2015

(54) GRAPHENE DISSIPATION STRUCTURE

(71) Applicant: Enerage Inc., Wujie Township (TW)

(72) Inventors: Mark Y. Wu, Wujie Township (TW); Cheng-Yu Hsieh, Wujie Township (TW); Jing-Ru Chen, Wujie Township (TW); Shu-Ling Hsieh, Wujie Township (TW); Kuan-Ting Li, Wujie Township (TW)

(21) Appl. No.: 14/594,730

(22) Filed: Jan. 12, 2015

(30) Foreign Application Priority Data
Apr. 29, 2014 (TW) 103115400

(51) Int. Cl. H05K 7/20

(52) U.S. Cl. CPC H05K 7/20427

(57) ABSTRACT

Disclosed is a graphene dissipation structure including a substrate and a graphene dissipation layer. The substrate has at least two surfaces. One of the surfaces contacts at least one heat source, and another one is not in contact with the heat source and provided with the graphene dissipation layer, which includes surface-modified graphene nanometer sheets, a carrier resin and a filler. The surface-modified graphene nanometer sheets are well dispersed in the carrier resin, and enhanced to contact each other through the filler to form a thermal conductive network. The ratio of the particle size of the filler and the thickness of the graphene nanometer sheets is about 2 to 100. Therefore, the heat absorbed by the substrate from the heat source is transferred to the graphene dissipation layer, and further dissipated to the outside through thermal conduction or radiation, thereby achieving the function of heat dissipation.

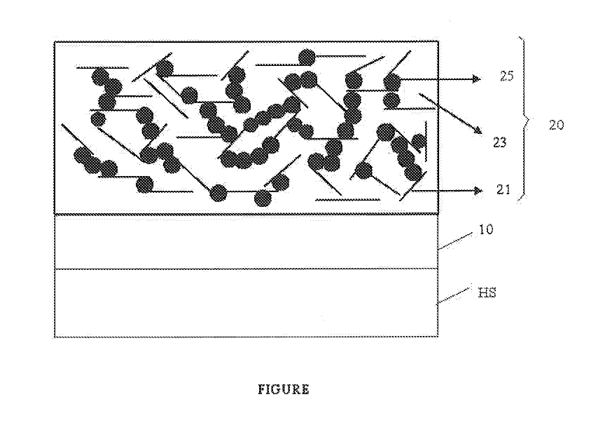

### CROSS-REFERENCE TO RELATED APPLICATION

This application claims the priority of Taiwanese patent application No. 103115400, filed on Apr. 29, 2014, which is incorporated, herewith by reference.

### BACKGROUND OF THE INVENTION

1. Field of the Invention

The present invention generally relates to a graphene dissipation structure, and more specifically to a graphene dissipation structure having a graphene dissipation layer formed of surface-modified graphene nanometer sheets uniformly dispersed in a carrier resin and enhanced to contact each other through a filler so as to improve thermal conductivity and electrical conductivity.

2. The Prior Arts

Since Andre Geim and Konstantin Novosclov at the University of Manchester in the UK in 2004 successfully proved that graphene is obtained from a piece of graphite by using adhesive tape, and were thus awarded the Nobel Prize in Physics for 2010, graphene has been well studied and widely applied to various fields due to its excellent electrical conductivity, thermal conductivity, chemical resistance, and so on. In general, graphene is 0.335 nm in thickness, about only one carbon diameter, and constructed by two-dimensional crystal bonded with sp² hybrid orbital in a form of hexagonal honeycomb. It is believed that graphene is the thinnest material in the world, and its mechanical strength is larger than steel by one hundred times more with its specific gravity of only one fourth of steel. Particularly, graphene is also an excellent material with thermal conductivity and electrical conductivity. The theoretical thermal conductivity is even up to 5300 W/mK such that graphene is one of ideal materials for heat dissipation.

However, one of the problems often caused in the actual application of graphene is that graphene is easy to congregate or get stacked to form a bulk. That is, it is hard for graphene to be uniformly dispersed. Thus, it is the primary bottleneck for the present industries to prevent graphene sheets from being stacked on each other so as to obtain graphene powder with high uniformity and less layers becomes.

Additionally, as the semiconductor technologies get fast progresses and various electrical functions are greatly enhanced, power consumption of the product is thus increased. To meet the demand of much lighter and smaller electronic devices, the power density for the electrical operation becomes further increased. It is needed for the powerful heat dissipation with smaller size and higher efficiency of heat dissipation to prevent failure or damage due to overheat, thereby ensuring the lifetime of the electronic products.

In the prior arts, CN 103107147 disclosed a heat dissipation device coated with a graphene film. The graphene film or the carrier containing the graphene film is previously manufactured and then attached onto the heat dissipation device by use of the backing adhesive or other physically fixing means. In such a structure of the heat dissipation device, overall heat resistance along the heat transfer route from the heat source to the graphene film is disadvantageously increased by the backing adhesive, the carrier layer and other fixing means configured between the graphene film and the heat source. Thus, one shortcoming of this technology is that the transfer rate of the heat generated by the heat source is substantially constrained by the effective thermal junction, thereby greatly limiting the efficiency of heat dissipation.

Another CN 102964972A disclosed a composite reinforced heat dissipation coating material containg graphene or graphene oxide. The reflux process is performed to cover the infrared powder with graphene or graphene oxide to reduce heat resistance for infrared light. Thus, the composite reinforced heat dissipation coating material is obtained. One drawback of this patent is that graphene has poor contact with the infrared powder and heat resistance of the junction is only slightly reduced, leading to low efficiency of heat dissipation. Additionally, the coating material needs to be uniformly dispersed in some specific solvent and the dispersion is then coated on the surface of the target object. Finally, the solvent is removed by heating or natural evaporation. The resultant heat dissipation coating layer has weak adhesion due to poor contact. In particular, the above process of removing the solvent may cause risky issue harmful to human, environment and industrial safety.

Therefore, it is greatly needed to provide a new graphene dissipation structure employing the surface-modified graphene nanometer sheets with the specific functional group on its surface, which greatly improves affinity with the functional group of the carrier resin to form the composite material. Especially, the surface-modified graphene nanometer sheets are enhanced to effectively contact each other through the filler so as to further increasing thermal conductivity and electrical conductivity. As a result, the substrate of the present invention receives the heat transferred from the heat source and further transfers the heat to the surface-modified layer, and the surface-modified layer dissipates the heat to the outside through thermal conduction or radiation, thereby achieving the effect of enhancing heat dissipation and overcoming the above problems in the prior arts.

### SUMMARY OF THE INVENTION

The primary objective of the present invention is to provide a graphene dissipation structure, which primarily comprises a substrate and a graphene dissipation layer. The substrate has a plurality of surfaces, at lest comprising a first surface and a second surface. The first surface is in contact with at least one heat source, and the graphene dissipation layer is provided on the second surface. Specifically, the graphene dissipation layer is thermally conductive and comprises a plurality of surface-modified graphene nanometer sheets, a carrier resin and a filler. The surface-modified graphene nanometer sheets are uniformly dispersed in the carrier resin and enhanced to contact each other through the filler.

Preferably, the ratio of the particle size of the filler and the thickness of the surface-modified graphene nanometer sheet is between 2 and 100.

Moreover, the substrate is selected from metal or graphite. The metal is selected from a group consisting of at least one of aluminum, copper, titanium and nickel, or alloy thereof. The thickness of the surface-modified graphene nanometer sheet is less than 50 μm. For the composition of the graphene dissipation layer, the surface-modified graphene nanometer sheet is 0.1-20% by weight, the filler is 20-80% by weight, and the carrier resin is 10-50% by weight.

The surface-modified graphene nanometer sheet at least comprises a surface-modified layer formed on its surface. Specifically, the surface-modified layer comprises at least one functional group, which is selected from a group consisting of vinyl, fatty alkylene oxide group, styryl, methacrylicoxyl, acrylicoxyl, fatty amino, propyl chloride group, fatty thiohydroxy, fatty sulfido group, socyanato group, fatty urea group, fatty carboxyl, fatty hydroxyl, cyclohexyl, phenyl, fatty formyl, acetyl and benzoyl.

The carrier resin is preferably selected from a group consisting of at least one of polyvinylidene fluoride, polytetrafluoroethylene, Polyethylene terephthalate, polyurethane, poly ethylene oxide, polyacrylonitrile, polyacrylamide, polyacrylate, polymethacrylate, polyvinyl acetate, polyvinylpyrrolidone, polytetraethylene glycol dimethacrylate, polyimide, cellulose acetate, cellulose acetate butyrate, cellulose acetate propionate, ethyl cellulose, cyanoethyl cellulose, polycyanoethyl alcohol, carboxymethyl cellulose, epoxy resin, phenolic resin and silicone.

The filler is selected from a group consisting of at least one of metal particle, ceramic particle, graphite, carbon nanotube and carbon black. The metal particle is selected from a group consisting of at least one of gold, silver, copper, titanium and aluminum, and the ceramic particle is selected from a group consisting of at least one of aluminum nitride, boron nitride, silicon nitride, silicon carbide, aluminum oxide and silicon oxide.

The above graphene dissipation structure has a planar thermal transfer rate larger than 400 W/mK, and the graphene dissipation layer being thermally conductive has sheet resistance less than 100 ohm/sq.

Since the surface-modified graphene nanometer sheet increases its dispersion and affinity in the carrier resin, and the surface-modified graphene nanometer sheets are enhanced to contact each other through the filler, the graphene dissipation layer with excellent thermal conductivity and electrical conductivity is obtained. Therefore, the substrate of the graphene dissipation structure according to the present invention receives the heat transferred from the heat source, and further transfers the heat to the surface-modified layer, and the surface-modified layer dissipates the heat to the outside through thermal conduction or radiation, thereby achieving the effect of enhancing heat dissipation.

### BRIEF DESCRIPTION OF THE DRAWINGS

The present invention can be understood in more detail by reading the subsequent detailed description in conjunction with the examples and references made to the accompanying drawings, wherein:

FIGURE is a sectional view schematically showing the graphene dissipation structure according to the present invention.

### DETAILED DESCRIPTION OF THE PREFERRED EMBODIMENT

The present invention may be embodied in various forms and the details of the preferred embodiments of the present invention will be described in the subsequent content with reference to the accompanying drawings. The drawings (not to scale) show and depict only the preferred embodiments of the invention and shall not be considered as limitations to the scope of the present invention. Modifications of the shape of the present invention shall too be considered to be within the spirit of the present invention.

Please refer to FIGURE showing the graphene dissipation structure according to the present invention. As shown in FIGURE, the graphene dissipation structure of the present invention generally comprises a substrate 10 and a graphene dissipation layer 20. The substrate 10 has a plurality of surfaces, at lest comprising the first surface (the lower surface) facing downward and the second surface (the upper surface) facing upward. The first surface is in contact with at least one heat source HS. Specifically, the graphene dissipation layer 20 is provided on the second surface of the substrate 10. The graphene dissipation layer 20 is thermally conductive and comprises a plurality of surface-modified graphene nanometer sheets 21, a carrier resin 23 and a filler 25. The surface-modified graphene nanometer sheets 21 are uniformly dispersed in the carrier resin 23 and enhanced to contact each other through the filler 25 so as to form a structure of electrical conductive with and thermal conductive network.

It should be noted that FIGURE is simplified to show each surface-modified graphene nanometer sheet 21 as a thin flake viewed from one side for the purpose of clear explaining the technical characteristics of the present invention. In other words, all the surface-modified graphene nanometer sheets 21 are randomly arranged and each one may actually show a different view.

It is preferred that the above substrate 10 is selected from metal or graphite, and the metal is selected from a group consisting of at least one of aluminum, copper, titanium and nickel, or alloy thereof. The thickness of the graphene dissipation layer 20 is less than 50 μm. The surface-modified graphene nanometer sheet 21 is 0.1-20% by weight, the carrier resin 23 is 10-50% by weight, and the filler 25 is 20-80% by weight.

More specifically, the surface-modified graphene nanometer sheet 21 at least comprises a surface-modified layer formed on the surface of the surface-modified graphene nanometer sheet 21, and the surface-modified layer comprises at least one functional group for improving affinity with the carrier resin 23 so such that the surface-modified graphene nanometer sheets 21 are easily and uniformly dispersed in the carrier resin 23.

The functional group of the surface-modified layer is selected from a group consisting of vinyl, fatty alkylene oxide group, styryl, methacrylicoxyl, acrylicoxyl, fatty amino, propyl chloride group, fatty thiohydroxy, fatty sulfido group, socyanato group, fatty urea group, fatty carboxyl, fatty hydroxyl, cyclohexyl, phenyl, fatty formyl, acetyl and benzoyl.

The carrier resin 23 of the graphene dissipation layer 20 is preferably selected from a group consisting of at least one of polyvinylidene fluoride, polytetrafluoroethylene, Polyethylene terephthalate, polyurethane, poly ethylene oxide, polyacrylonitrile, polyacrylamide, polyacrlylate, polymethacrylate, polyvinyl acetate, polyvinylpyrrolidone, polytetraethylene glycol dimethacrylate, polyimide, cellulose acetate, cellulose acetate butyrate, cellulose acetate propionate, ethyl cellulose, cyanoethyl cellulose, polycyanoethyl alcohol , carboxymethyl cellulose, epoxy resin, phenolic resin and silicone.

Furthermore, the filler 25 is formed of thermally conductive solid particles, powder, lakes or filaments. The primary object of the filler 25 is to increase the overall contact effect for the surface-modified graphene nanometer sheets 21, thereby enhancing the efficiency of thermal transfer. Each surface-modified graphene nanometer sheet 21 substantially has a thin flake shape, and if all the surface-modified graphene nanometer sheets 21 contact each other with the planar sides in case of no the filler 25, the contact area is certainly the largest such that the heat transfer rate is optimized. However, since the surface-modified graphene nanometer sheets 21 are uniformly dispersed in the carrier resin 23, in addition to the planar sides, the adjacent surface-modified graphene nanometer sheets 21 at the different locations may contact with the edges or corners. As a result, the contact area is reduced and the efficiency of heat transfer is lowered because heat transfer is basically proportional to the effective contact area. Therefore, the filler 25 is added and physically contacts at least part of the surface-modified graphene nanometer sheets 21 so as to provide additional effective contact area for the adjacent surface-modified graphene nanometer sheets 21, thereby increasing the efficiency of heat transfer.

In particular, based on the above features, the ratio of the particle size of the filler 25 and the thickness of the surface-modified graphene nanometer sheet 21 is preferably between 2 and 100.

It is preferred that the tiller 25 is selected from a group consisting of at least one of metal particle, ceramic particle, graphite, carbon nanotube and carbon black. The metal particle is selected from a group consisting of at least one of gold, silver, copper, titanium and aluminum, and the ceramic particle is selected from a group consisting of at least one of aluminum nitride, boron nitride, silicon nitride, silicon carbide, aluminum oxide and silicon oxide.

Overall speaking, the above graphene dissipation structure according to the present invention has a planar heat transfer rate larger than 400 W/mK, and the graphene dissipation layer 20 has excellent sheet resistance less than 100 ohm/sq. Therefore, the present invention provides both excellent thermal conductivity and electrical conductivity.

To further illustrate the practical benefits provided by the graphene dissipation structure according to the present invention, some following experimental examples are described in more details to help those skilled in this technical field well understand the practical processes of the present invention.

### Experimental Example 1

Here, the illustrative recipe includes polyurethane (48% by weight) as the carrier resin, carbon black (40% by weight) as the filler, and the surface-modified graphene nanometer sheet (12% by weight). Additionally, aluminum foil is used as the substrate,

First, the ingredients of the above recipe are pre-blended, and then well mixed at 8000 rpm for 8 hours in an emulsifier, obtaining a slurry containing the graphene dissipation layer. Next, the slurry is coated on the aluminum foil by means of the doctor blade, and thermally processed at 70° C. in an oven or on a heat plate to remove all liquid and solidify the slurry. As a result, the graphene dissipation structure as desired is manufactured.

The above graphene dissipation structure is forced to contact the heat source at 75° C. for 10 minutes to achieve thermal equilibrium. An infrared sensing gun is used to measure the surface temperature of the graphene dissipation structure. The measured temperature is 65.6° C., which is lowered by 9.4° C. with respect to the original surface temperature of the heat source. Further in comparison with the aluminum foil without being coated with the graphene dissipation layer, the temperature is measured as 69.4° C., lowered by only 5.6° C.

### Experimental Example 2

The recipe is the same as the previous Experimental example 1 with polyurethane (48% by weight), carbon black (40% by weight) and the surface-modified graphene nanometer sheet (12% by weight). The copper foil is used as the substrate, instead of aluminum foil.

All the ingredients are pre-blended, and then well mixed at 8000 rpm for 8 hours in the emulsifier to obtain the slurry containing the graphene dissipation layer. The slurry is coated on the copper foil by the doctor blade, and heated at 70° C. in the oven or on the heat plate to obtain the graphene dissipation structure after the slurry is solidified.

Similarly the graphene dissipation structure contacts the heat source at 75° C. for 10 minutes to attain thermal equilibrium. The surface temperature of the graphene dissipation structure is measured as 62.7° C. by the infrared sensing gun, lowered by 12.3° C. with respect to the original surface temperature of the heat source.

Also, the copper foil without being coated with the graphene dissipation layer is further compared and has the surface temperature of 66.4° C., lowered by only 8.6° C.

### Experimental Example 3

This recipe employs polyurethane (30.5% by weight), carbon black (53% by weight) and the surface-modified graphene nanometer sheet (16.5% by weight). An aluminum thermal dissipation fin is used as the substrate.

The above ingredients are pre-blended and then well mixed at 8000 rpm for 8 hours in the emulsifier to obtain the slurry containing the graphene dissipation layer. The slurry is coated on the aluminum thermal dissipation fin by the doctor blade, and heated at 70° C. in the oven or on the heat plate to obtain the graphene dissipation structure after the slurry is solidified.

The graphene dissipation structure obtained is similarly in contact with the heat source at 75° C. for 10 minutes to attain thermal equilibrium. The surface of the graphene dissipation structure is measured as 67.9° C. by the infrared sensing gun, lowered by 7.1° C. with respect to the original surface temperature of the heat source.

From the above examples 1, 2 and 3, it is obvious to understand that the graphene dissipation structure of the present invention can improve the efficiency of heat dissipation, thereby providing industrial utility.

One of the primary features of the present invention is that the surface-modified graphene nanometer sheets improves dispersity and affinity in the carrier resin, and are greatly enhanced to contact each other through the filler such that the substrate of the graphene dissipation structure receives the heat from the heat source and further transfers the heat to the graphene dissipation layer, the graphene dissipation layer dissipate the heat to the outside through thermal conduction or radiation, thereby improving the efficiency of heat dissipation. Therefore, the present invention is suitable for the electrical elements or devices requiring heat dissipation.

Although the present invention has been described with reference the preferred embodiments, it will be understood that the invention is not limited to the details described thereof Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A graphene dissipation structure, comprising:
a substrate comprising a plurality of surfaces, the surfaces at lest comprising a first surface and a second surface, and the first surface in contact with at least one heat source; and
a graphene dissipation layer being thermally conductive and provided on the second surface of the substrate, wherein the graphene dissipation layer comprises a plurality of surface-modified graphene nanometer sheets, a carrier resin and a filler, the surface-modified graphene nanometer sheets are uniformly dispersed in the carrier resin and in contact with each other through the filler, a ratio of a particle size of the filler and a thickness of the surface-modified graphene nanometer sheet is between 2 and 100, the surface-modified graphene nanometer sheet is 0.1-20% by weight, the filler is 20-80% by weight, and the carrier resin is 10-50% by weight.

2. The graphene dissipation structure as claimed in claim 1, wherein the thickness of the graphene dissipation layer is less than 50 μm.

3. The graphene dissipation structure as claimed in claim 1, wherein the graphene dissipation layer has sheet resistance less than 100 ohm/sq.

4. The graphene dissipation structure as claimed in claim 1, wherein the substrate is selected from metal or graphite, and the metal is selected from a group consisting of at least one of aluminum, copper, titanium and nickel, or alloy thereof.

5. The graphene dissipation structure as claimed in claim 1, wherein the surface-modified graphene nanometer sheet at least comprises a surface-modified layer formed on a surface of the surface-modified graphene nanometer sheet, the surface-modified layer comprises at least one functional group selected from a group consisting of vinyl, fatty alkylene oxide group, styryl, methacrylicoxyl, acrylicoxyl, fatty amino, propyl chloride group, fatty thiohydroxy, fatty sulfide group, socyanato group, fatty urea group, fatty carboxyl, fatty hydroxyl, cyclohexyl, phenyl, fatty formyl, acetyl and benzoyl.

6. The graphene dissipation structure as claimed in claim 1, wherein the carrier resin is selected from a group consisting of at least one of polyvinylidene fluoride, polytetrafluoroethylene, Polyethylene terephthalate, polyurethane, poly ethylene oxide, polyacrylonitrile, polyacrylamide, polyacrylate, polymethacrylate, polyvinyl acetate, polyvinylpyrrolidone, polytetraethylene glycol dimethacrylate, polyimide, cellulose acetate, cellulose acetate butyrate, cellulose acetate propionate, ethyl cellulose, cyanoethyl cellulose, polycyanoethyl alcohol, carboxymethyl cellulose, epoxy resin, phenolic resin and silicone.

7. The graphene dissipation structure as claimed in claim 1, wherein the filler is selected from a group consisting of at least one of metal particle, ceramic particle, graphite, carbon nanotube and carbon black, the metal particle is selected from a group consisting of at least one of gold, silver, copper, titanium and aluminum, and the ceramic particle is selected from a group consisting of at least one of aluminum nitride, boron nitride, silicon nitride, silicon carbide, aluminum oxide and silicon oxide.
